(19) United States
(12) Patent Application Publication
(10) Pub. No.: US 2025/0113653 A1
(43) Pub. Date: Apr. 3, 2025

(54) THERMOELECTRIC CONVERSION DEVICE, CONTROLLING METHOD, AND METHOD OF GENERATING ELECTRIC POWER

(71) Applicant: Panasonic Intellectual Property Management Co., Ltd., Osaka (JP)

(72) Inventors: HIROMASA TAMAKI, Osaka (JP); ATSUSHI ONO, Kyoto (JP)

(21) Appl. No.: 18/973,163

(22) Filed: Dec. 9, 2024

Related U.S. Application Data
(63) Continuation of application No. PCT/JP2023/023042, filed on Jun. 22, 2023.

(30) Foreign Application Priority Data
Jul. 7, 2022 (JP) 2022-110072

(51) Int. Cl. H10F 77/42; H10N 10/10

(52) U.S. Cl. CPC H10F 77/488; H10N 10/10

(57) ABSTRACT

A thermoelectric conversion device includes a reflecting member that has an opening portion through which radiant heat from a heat source passes, and a concave reflecting surface that reflects the radiant heat that has passed through the opening portion; a thermoelectric conversion member that converts heat into electric power; and a heat collector that is disposed between the reflecting member and the thermoelectric conversion member, and that is disposed such that at least a part of the heat collector faces the reflecting surface of the reflecting member. The heat collector includes a heat-collecting region that absorbs the radiant heat reflected by the reflecting surface of the reflecting member, and a heat transfer region that transfers the radiant heat absorbed by the heat-collecting region to the thermoelectric conversion member.

### BACKGROUND

### 1. Technical Field

The present disclosure relates to a thermoelectric conversion device, a controlling method, and a method of generating electric power.

### 2. Description of the Related Art

Japanese Unexamined Patent Application Publication No. 2013-69975 (PTL 1) discloses a thermoelectric conversion device including a light-gathering heat-collecting unit that is disposed so as not to contact a heat source that radiates radiant heat.

Japanese Unexamined Patent Application Publication No. 2013-128333 (PTL 2) discloses a thermoelectric conversion device in which sunlight is reflected toward a heat collector by a reflecting plate, and heat of the sunlight received by the heat collector is transferred to a heat transfer medium that passes through the inside of the heat collector.

### SUMMARY

One non-limiting and exemplary embodiment provides a thermoelectric conversion device, a controlling method, and a method of generating electric power, which can convert heat obtained by radiant heat into electric power with high efficiency.

In one general aspect, the techniques disclosed here feature a thermoelectric conversion device including a reflecting member that has an opening portion through which radiant heat from a heat source passes, and a concave reflecting surface that reflects the radiant heat that has passed through the opening portion; a thermoelectric conversion member that converts heat into electric power; and a first heat collector that is disposed between the reflecting member and the thermoelectric conversion member, and that is disposed such that at least a part of the first heat collector faces the reflecting surface of the reflecting member, wherein the first heat collector includes a heat-collecting region that absorbs the radiant heat reflected by the reflecting surface of the reflecting member, and a heat transfer region that transfers the radiant heat absorbed by the heat-collecting region to the thermoelectric conversion member.

According to the thermoelectric conversion device according to the one general aspect of the present disclosure, heat obtained by radiant heat can be converted into electric power with high efficiency.

It should be noted that general or specific embodiments may be implemented as a device, a method, or any combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a perspective view showing a thermoelectric conversion device according to a first embodiment;

FIG. 2A is a sectional view of the thermoelectric conversion device according to the first embodiment along line II-II of FIG. 1;

FIG. 2B is a perspective view showing a cooler according to the first embodiment;

FIG. 3 is a schematic view for illustrating an operation of the thermoelectric conversion device according to the first embodiment;

FIG. 4 is a graph showing dependence of a high-temperature-side temperature of a thermoelectric conversion member on the temperature of a heat source;

FIG. 5 is a sectional view of a thermoelectric conversion device according to a modification of the first embodiment;

FIG. 6 is a sectional view of a heat collector according to Modification 1 of the first embodiment;

FIG. 7 is a sectional view of a heat collector according to Modification 2 of the first embodiment;

FIG. 8 is a sectional view of a heat collector according to Modification 3 of the first embodiment;

FIG. 9 is a schematic view showing a thermoelectric conversion device according to a second embodiment;

FIG. 10 is a schematic view showing a thermoelectric conversion device according to a third embodiment;

FIG. 11 is a block diagram showing a functional structure of a thermoelectric conversion system according to a fourth embodiment;

FIG. 12 is a schematic view for illustrating Control Example 1 of a controlling device according to the fourth embodiment;

FIG. 13 is a schematic view for illustrating Control Example 2 of the controlling device according to the fourth embodiment;

FIG. 14 is a schematic view for illustrating Control Example 3 of the controlling device according to the fourth embodiment;

FIG. 15 is a sectional view of a thermoelectric conversion device according to a fifth embodiment;

FIG. 16 is a sectional view of a thermoelectric conversion device according to a sixth embodiment;

FIG. 17 is a sectional view of a thermoelectric conversion device according to a seventh embodiment;

FIG. 18 is a sectional view of a thermoelectric conversion device according to an eighth embodiment;

FIG. 19 is a diagram for illustrating a first region and a second region;

FIG. 20 is a diagram for illustrating the first region and the second region;

FIG. 21 is a diagram for illustrating a first region and a second region;

FIG. 22 is a diagram for illustrating a first region and a second region;

FIG. 23 is a diagram for illustrating a first region and a second region;

FIG. 24 is a diagram for illustrating a first region and a second region; and

FIG. 25 is a diagram for illustrating a guide.

### DETAILED DESCRIPTIONS

### Underlying Knowledge Forming Basis of the Present Disclosure

The present inventors have found out that, with regard to the technologies described in the “Description of the Related Art” section, the following problems occur.

Thermoelectric power generation using the Seebeck effect has been put into practical use as, for example, power sources for remote areas or space power sources, and is expected in the future to be more widely used for collecting and using unused exhaust heat to reduce CO₂ emissions.

The energy conversion efficiency from heat to electricity in thermoelectric power generation is determined by a figure of merit ZT of a material that is used. The energy conversion efficiency becomes higher as the figure of merit ZT increases, and a high figure of merit ZT is realized in a semiconductor into which electrically conductive carriers have been injected.

As one form of unused exhaust heat, there exists radiant heat from a heated high-temperature medium. For example, in a step of processing a structure made of metal or ceramic, the structure heated to about 500° C. to 1000° C. is cooled while radiating, as radiant heat, heat energy with respect to a space. The radiant heat radiated from the structure is ordinarily dissipated without being used. Effective use of such unused radiant heat is important in increasing the energy efficiency in the processing step and reducing CO₂ emissions.

In a thermoelectric conversion device including a thermoelectric conversion module, it is possible to perform thermoelectric power generation by using radiant heat. Specifically, it is possible to, by heating one surface of the thermoelectric conversion module with radiant heat and cooling the other surface of the thermoelectric conversion module, cause a temperature difference to occur between the one surface and the other surface of the thermoelectric conversion module and to convert heat energy into electric power. In such a thermoelectric conversion device, since a movable part does not exist and the power generation amount can be obtained in proportion to the area of the thermoelectric conversion module, the thermoelectric conversion module has an advantage in that a compact unit that is formed in accordance with, for example, the exhaust heat amount, position, and form can be realized.

Incidentally, PTL 1 discloses a thermoelectric conversion device including a light-gathering heat-collecting unit that is disposed so as not to contact a heat source that radiates radiant heat. In PTL 1, the light-gathering heat-collecting unit is used to gather sunlight with a lens, to convert light into heat by a sunlight selective absorption material, and to supply the heat after the conversion as radiant heat to a heat receiving plate. However, when a light gathering technology using a lens such as that disclosed in PTL 1 is used with respect to radiant heat less than or equal to 1000° C., since the transmittance of the lens with respect to a spectral region greater than or equal to a wavelength of 3 μm, which becomes a main component, is low, energy loss occurs. Infrared lenses made of a material, such as Ge (germanium), are difficult to process, are difficult to form with a larger area, and are costly, and thus it is not practical to use infrared lenses in a thermoelectric conversion device.

PTL 2 discloses a thermoelectric conversion device in which sunlight is reflected toward a heat collector by a reflecting plate, and heat of the sunlight received by the heat collector is transferred to a heat transfer medium that passes through the inside of the heat collector. In addition, PTL 2 discloses that heat that has been transferred to the heat transfer medium is thermoelectrically converted by using a thermoelectric conversion module. However, in PTL 2, since the heat transfer medium goes through a two-stage heat-exchange process, in which, in the heat collector, the heat transfer medium is heated and the heat transfer medium heats the thermoelectric conversion module, heat is dissipated and the heat amount is lost when the heat transfer medium flows through a pipe. Therefore, the temperature when the heat is received in the thermoelectric conversion module is decreased much more than the temperature when the heat is collected in the heat collector.

The present inventors have found out the following based on the above. That is, in particular, in low-quality radiant heat that is emitted from a medium whose temperature is less than or equal to 1000° C., since the energy density per unit area is low, when the thermoelectric conversion module receives heat without contacting the medium, the temperature difference before and after the reception of heat is considerably decreased. Based on this knowledge, the present inventors have contrived a thermoelectric conversion device according to the present disclosure.

A thermoelectric conversion device according to an aspect of the present disclosure includes a reflecting member that has an opening portion through which radiant heat from a heat source passes, and a concave reflecting surface that reflects the radiant heat that has passed through the opening portion; a thermoelectric conversion member that converts heat into electric power; and a first heat collector that is disposed between the reflecting member and the thermoelectric conversion member, and that is disposed such that at least a part of the first heat collector faces the reflecting surface of the reflecting member, wherein the first heat collector includes a heat-collecting region that absorbs the radiant heat reflected by the reflecting surface of the reflecting member, and a heat transfer region that transfers the radiant heat absorbed by the heat-collecting region to the thermoelectric conversion member.

According to the present aspect, the radiant heat from the heat source is absorbed by the heat-collecting region of the first heat collector after being reflected by the reflecting surface of the reflecting member. In addition, the radiant heat absorbed by the heat-collecting region of the first heat collector is transferred to the thermoelectric conversion member from the heat transfer region of the first heat collector. Therefore, the radiant heat from the heat source can be efficiently transferred to the thermoelectric conversion member, and heat obtained by the radiant heat can be converted into electric power with high efficiency.

The thermoelectric conversion device may further include a heat-insulating member that is disposed at at least a part of the heat transfer region.

According to the present aspect, it is possible to suppress radiation of the radiant heat from the heat transfer region of the first heat collector and to efficiently transfer the radiant heat absorbed by the heat-collecting region to the thermoelectric conversion member.

At least a part of the first heat collector may be sandwiched between the heat-insulating member and the thermoelectric conversion member.

According to the present aspect, since at least a part of the first heat collector is pushed against the thermoelectric conversion member by the heat-insulating member, the radiant heat absorbed by the heat-collecting region of the first heat collector can be efficiently transferred to the thermoelectric conversion member.

The heat-collecting region may have a projecting structure that projects toward the opening portion from the reflecting surface of the reflecting member, the projecting structure may have an end portion and a side surface, and the heat-insulating member may be disposed along the side surface of the projecting structure.

According to the present aspect, the radiant heat from the heat source can be absorbed by the end portion of the projecting structure. In addition, since the heat-insulating member is disposed along the side surface of the projecting structure, the radiant heat absorbed by the end portion of the projecting structure can be efficiently transferred to the thermoelectric conversion member.

The thermoelectric conversion device may further include a heat storage member that stores heat absorbed by the heat-collecting region, wherein the heat storage member may be disposed between the side surface of the projecting structure and the heat-insulating member.

According to the present aspect, even if the heat reception amount in the heat-collecting region of the first heat collector varies, it is possible to smoothen out changes in the temperature difference in the thermoelectric conversion member with time, and to more stably perform thermoelectric power generation.

An emissivity of a surface of the heat-collecting region may be greater than or equal to 0.8, and a heat conductivity of an inner portion of the heat-collecting region may be greater than or equal to 20 W/mK.

According to the present aspect, the radiant heat from the heat source can be efficiently absorbed by the surface of the heat-collecting region, and the absorbed radiant heat can be efficiently transferred to the thermoelectric conversion member from the inner portion of the heat-collecting region.

The surface of the heat-collecting region may be subjected to alumite treatment, or may be coated with a black paint.

According to the present aspect, it is possible to increase the emissivity of the surface of the heat-collecting region, and the radiant heat from the heat source can be efficiently absorbed by the surface of the heat-collecting region.

A cross-sectional shape of the reflecting surface of the reflecting member may include at least one of an elliptical arc shape, an arc shape, or a parabolic shape.

According to the present aspect, the radiant heat reflected by the reflecting surface of the reflecting member can be efficiently absorbed by the heat-collecting region of the first heat collector.

The thermoelectric conversion device may further include a cooler that cools the thermoelectric conversion member; and a fixing member that fixes the reflecting member and the first heat collector to each other, wherein the thermoelectric conversion member may have a first main surface that contacts the heat transfer region of the first heat collector, and a second main surface that contacts the cooler.

According to the present aspect, the positional relationship between the reflecting member and the first heat collector can be kept constant by the fixing member.

The thermoelectric conversion device may further include a second heat collector that is disposed at the opening portion so as to oppose the reflecting surface of the reflecting member, and that absorbs the radiant heat from the heat source.

According to the present aspect, even if the radiation direction of the radiant heat (infrared rays) from the heat source varies, the heat collecting point in the heat-collecting region can be kept constant.

The thermoelectric conversion device may further include a third heat collector that is disposed between the heat source and the opening portion of the reflecting member, wherein the third heat collector may absorb heat from the heat source, and may radiate, as the radiant heat, the heat that has been absorbed toward the reflecting member.

According to the present aspect, the heat of the heat source is transferred to the third heat collector, and the heat transferred to the third heat collector is radiated as radiant heat toward the reflecting member from the third heat collector. Therefore, the heat of the heat source can be efficiently absorbed by the heat-collecting region of the first heat collector.

A controlling method according to an aspect of the present disclosure is a controlling method that is performed by a controlling device for controlling any one of the thermoelectric conversion devices above, wherein the controlling device (a) obtains position information indicating a positional relationship between the heat source and the thermoelectric conversion device; (b) based on at least the position information obtained in the (a), generates a first control signal including changing information for instructing the thermoelectric conversion device to change at least one of a position or an angle of the thermoelectric conversion device with respect to the heat source; and (c) sends the first control signal generated in the (b) to the thermoelectric conversion device.

According to the present aspect, the radiant heat from the heat source can be efficiently transferred to the thermoelectric conversion member, and heat obtained by the radiant heat can be converted into electric power with high efficiency.

In the controlling method, in the (b), the first control signal including the changing information is generated based on heat-source temperature information and the position information, the heat-source temperature information indicating an ambient temperature of the heat source; and the first control signal includes the changing information for instructing the thermoelectric conversion device to perform at least one of (1) changing at least one of the position or the angle of the thermoelectric conversion device with respect to the heat source such that a temperature of the first heat collector in the thermoelectric conversion device becomes higher than a first temperature; (2) changing at least one of the position or the angle of the thermoelectric conversion device with respect to the heat source so as to follow a change in the ambient temperature of the heat source indicated by the heat-source temperature information; or (3) changing at least one of the position or the angle of the thermoelectric conversion device with respect to the heat source such that the thermoelectric conversion device moves away from the heat source when the ambient temperature of the heat source indicated by the heat-source temperature information exceeds a second temperature.

According to the present aspect, the radiant heat from the heat source can be efficiently transferred to the thermoelectric conversion member, and heat obtained by the radiant heat can be converted into electric power with high efficiency.

A controlling method according to an aspect of the present disclosure is a controlling method that is performed by a controlling device for controlling the thermoelectric conversion device, wherein the controlling device (a) obtains heat-collector temperature information indicating an ambient temperature of the first heat collector; (b) based on the heat-collector temperature information obtained in the (a), generates a second control signal for controlling a cooling capability of the cooler of the thermoelectric conversion device; and (c) sends the second control signal generated in the (b) to the thermoelectric conversion device.

According to the present aspect, it is possible to increase the efficiency of thermoelectric power generation in the thermoelectric conversion member.

A method of generating electric power according to an aspect of the present disclosure includes reflecting radiant heat from a heat source having a peak wavelength that is greater than or equal to 3 μm; absorbing heat obtained by the radiant heat that has been reflected; transferring the heat that has been absorbed; and converting the heat that has been transferred into the electric power.

According to the present aspect, heat obtained by the radiant heat can be converted into electric power with high efficiency.

It should be noted that general or specific embodiments may be implemented as a device, a method, or any combination thereof.

Embodiments are described below while referring to the drawings.

Note that the embodiments described below are all general or specific examples. In the embodiments below, numerical values, forms, materials, structural elements, arrangement positions and connection modes of the structural elements, steps, the order of steps, etc., are examples, and are not intended to limit the scope of the claims. In addition, of the structural elements in the embodiments below, the structural elements that are not described in independent claims that indicate the broadest concepts are described as optional structural elements. Each figure is not necessarily an exact illustration. In each of the figures, structures that are essentially the same are given the same reference numerals, and overlapping descriptions are omitted or simplified.

### First Embodiment

### 1-1. Structure of Thermoelectric Conversion Device

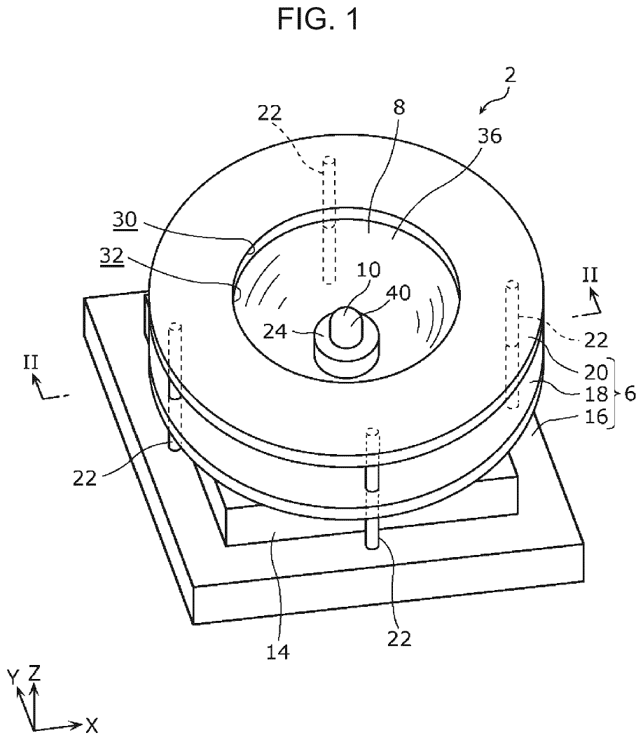

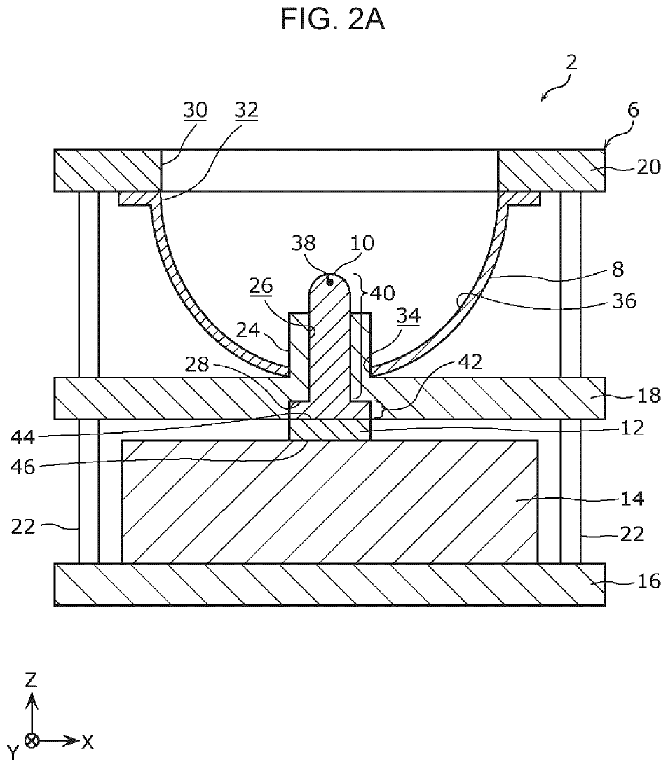

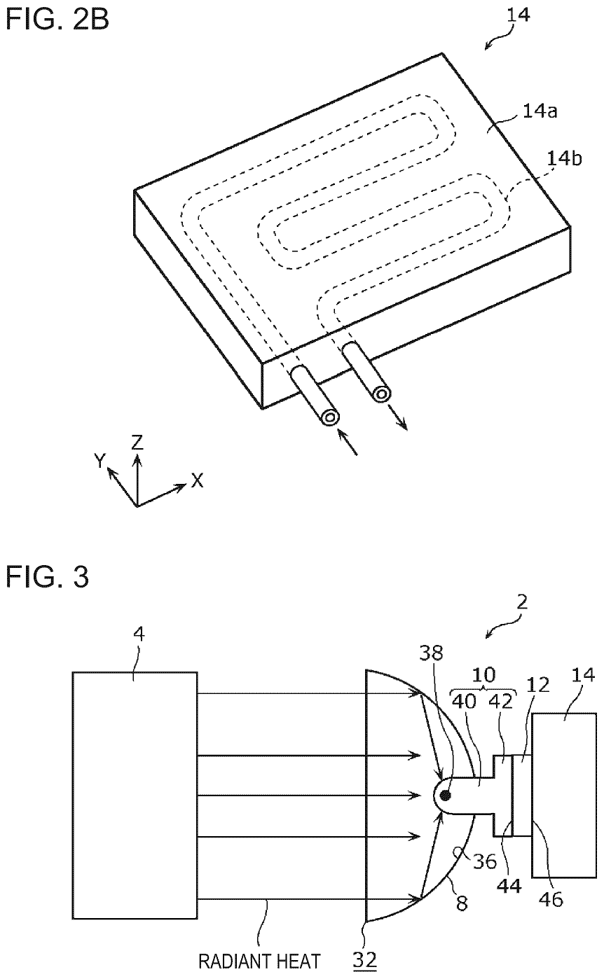

First, a structure of a thermoelectric conversion device 2 according to a first embodiment is described with reference to FIGS. 1 to 2B. FIG. 1 is a perspective view showing the thermoelectric conversion device 2 according to the first embodiment. FIG. 2A is a sectional view of the thermoelectric conversion device 2 according to the first embodiment along line II-II of FIG. 1. FIG. 2B is a perspective view showing a cooler 14 according to the first embodiment.

Note that, in FIGS. 1 to 2B, a left-right direction of the thermoelectric conversion device 2 is an X axis direction, a front-back direction of the thermoelectric conversion device 2 is a Y axis direction, and an up-down direction of the thermoelectric conversion device 2 is a Z axis direction.

The thermoelectric conversion device 2 is, for example, a thermoelectric conversion unit for generating electric power by using heat energy of radiant heat (infrared rays) radiated from a heat source 4 (see FIG. 3 described below). The heat source 4 is, for example, a structure made of metal or ceramic heated to about 500° C. to 1000° C. in a processing step in a plant or the like. A peak wavelength of the radiant heat that is radiated from the heat source 4 is, for example, greater than or equal to 3 μm.

As shown in FIGS. 1 and 2A, the thermoelectric conversion device 2 includes a fixing member 6, a reflecting member 8, a heat collector 10 (an example of a first heat collector), a thermoelectric conversion member 12, and the cooler 14.

The fixing member 6 is provided for fixing the reflecting member 8, the heat collector 10, and the cooler 14 to each other. The fixing member 6 includes a first plate 16, a second plate 18, a third plate 20, and connecting rods 22. The first plate 16, the second plate 18, and the third plate 20 are each made of a heat-insulating material. Therefore, the reflecting member 8, the heat collector 10, and the cooler 14 can be thermally insulated from each other by the fixing member 6 made of a heat-insulating material.

The first plate 16 is formed to have a rectangular flat plate shape. The cooler 14 is fixed to an upper surface of the first plate 16.

The second plate 18 is formed to have a circular flat plate shape and is disposed to oppose the upper surface of the first plate 16. A cylindrical supporting part 24 (an example of a heat-insulating member) is formed at a central portion of the second plate 18 in a radial direction thereof. The supporting part 24 projects toward the third plate 20 from an upper surface of the second plate 18. An insertion hole 26 for inserting the heat collector 10 is formed in the supporting part 24. A stepped portion 28 is formed at a lower end portion (end portion on a side facing the first plate 16) of the insertion hole 26.

The third plate 20 is formed to have an annular flat plate shape and is disposed to oppose the upper surface of the second plate 18. A circular opening portion 30 is formed in the third plate 20.

The connecting rods 22 connect the first plate 16, the second plate 18, and the third plate 20 to each other.

The reflecting member 8 is formed to have a bowl shape having a circular opening portion 32, and is made of, for example, aluminum. A peripheral edge portion of the opening portion 32 of the reflecting member 8 is fixed to a peripheral edge portion of the opening portion 30 of the third plate 20. An insertion hole 34 is formed in a bottom portion of the reflecting member 8, and the supporting part 24 of the second plate 18 is inserted in the insertion hole 34. A concave reflecting surface 36 that reflects radiant heat that has passed through the opening portion 32 is formed at an inner surface of the reflecting member 8. In sectional view in FIG. 2A, the cross-sectional shape of the reflecting surface 36 of the reflecting member 8 is formed to be, for example, a parabolic shape. When radiant heat is input in the form of a planar wave toward the reflecting surface 36, a heat-collecting point 38 where the radiant heat reflected by the reflecting surface 36 is collected is formed at a position of a parabolic focus defined by the reflecting surface 36 or in the vicinity thereof. That is, at the heat-collecting point 38, the density of infrared energy included in the radiant heat is maximized.

Note that, although, in the present embodiment, the cross-sectional shape of the reflecting surface 36 of the reflecting member 8 is formed to have a parabolic shape, the shape is not limited thereto, and the shape may be, for example, an elliptical arc shape, an arc shape, or a square shape. In addition, although, in the present embodiment, the reflecting member 8 is formed to have a bowl shape, the shape is not limited thereto, and the shape may be, for example, a cylindrical shape.

The heat collector 10 is disposed between the reflecting member 8 and the thermoelectric conversion member 12, and is disposed such that at least a part of the heat collector 10 faces the reflecting surface 36 of the reflecting member 8. The heat collector 10 includes a heat-collecting region 40 that absorbs radiant heat reflected by the reflecting surface 36 of the reflecting member 8, and a heat transfer region 42 that transfers the radiant heat absorbed by the heat-collecting region 40 as a heat flow to the thermoelectric conversion member 12.

The heat-collecting region 40 is formed to have a rod shape, and an end portion (upper end portion) of the heat-collecting region 40 is formed to have a semicircular shape. By inserting the heat-collecting region 40 into the insertion hole 26 of the supporting part 24 of the second plate 18, the heat-collecting region 40 is fixed to the second plate 18. The end portion of the heat-collecting region 40 projects from an upper end portion of the insertion hole 26 of the supporting part 24. Note that the heat-collecting point 38 described above is positioned on the end portion of the heat-collecting region 40. That is, the heat-collecting region 40 has a projecting structure that projects toward the opening portion 32 from the reflecting surface 36 of the reflecting member 8. In addition, the supporting part 24 of the second plate 18 is disposed along at least a part of the heat-collecting region 40, specifically, along a side surface of the heat-collecting region 40 (projecting structure).

The heat transfer region 42 is disposed at a base end portion (lower end portion) of the heat-collecting region 40, and is formed to have a flange shape that projects outward in a radial direction from the side surface of the heat-collecting region 40. The heat transfer region 42 is fitted to the stepped portion 28 formed at the lower end portion of the insertion hole 26 of the supporting part 24, and a lower surface of the heat transfer region 42 contacts a first main surface 44 (described below) of the thermoelectric conversion member 12. Therefore, the heat transfer region 42 is sandwiched between the stepped portion 28 of the supporting part 24 and the first main surface 44 of the thermoelectric conversion member 12.

The heat collector 10 is made of, for example, aluminum, and a surface of the heat collector 10 is subjected to alumite treatment. Therefore, it is possible to relatively increase the emissivity of the surface of the heat-collecting region 40 and to suppress reflection of radiant heat at the surface of the heat-collecting region 40. Here, the emissivity of the surface of the heat-collecting region 40 is preferably greater than or equal to 0.8 and more preferably greater than or equal to 0.9. The heat conductivity of an inner portion of the heat-collecting region 40 is preferably greater than or equal to 20 W/mK, and more preferably greater than or equal to 100 W/mK. Note that, instead of a structure such as that described above, the heat collector 10 may be made of a metal material having a relatively high heat conductivity, such as copper or nickel, and the surface of the heat collector 10 may be coated with a black paint.

The thermoelectric conversion member 12 is formed to have a rectangular flat plate shape, and is sandwiched between the cooler 14 and the heat transfer region 42 of the heat collector 10 from above and below the thermoelectric conversion member 12. That is, the thermoelectric conversion member 12 has the first main surface 44 that contacts the heat transfer region 42 of the heat collector 10, and a second main surface 46 (surface on a side opposite to the first main surface 44) that contacts the cooler 14. Therefore, the thermoelectric conversion member 12 performs, by the Seebeck effect, thermoelectric power generation in which heat energy is converted into electric power by a temperature difference between radiant heat absorbed by the heat-collecting region 40 of the heat collector 10 and cooling fluid flowing in the cooler 14.

The thermoelectric conversion member 12 is a thermoelectric conversion module having, for example, a x-type structure. Although not shown, in the thermoelectric conversion member 12 having a x-type structure, a P-type thermoelectric conversion element and an N-type thermoelectric conversion element are electrically connected to each other through an electrode. The P-type thermoelectric conversion element and the N-type thermoelectric conversion element are covered from two sides by two ceramic substrates. Each of the two ceramic substrates has the first main surface 44 and second main surface 46 described above. Note that the thermoelectric conversion member 12 may have a half-skeleton-type structure in which one side of each of the P-type thermoelectric conversion element and the N-type thermoelectric conversion element is covered by one ceramic substrate, or may have a full-skeleton structure in which a ceramic substrate is not used.

The material of each of the P-type thermoelectric conversion element and the N-type thermoelectric conversion element can be selected as appropriate in accordance with, for example, an operation condition, such as an applicable temperature range. For example, as the material of each of the P-type thermoelectric conversion element and the N-type thermoelectric conversion element, a Bi₂Te₃-based element, an SiGe-based element, a Half-Heusler-based element, a skutterudite-based element, or a PbTe-based element can be used. Alternatively, as the material of the P-type thermoelectric conversion element, a GeTe-based element can be used, and, as the material of the N-type thermoelectric conversion element, an Mg₃Sb₂-based element can be used.

The cooler 14 is fixed to the upper surface of the first plate 16 and contacts the second main surface 46 of the thermoelectric conversion member 12. The cooler 14 is constituted by, for example, a water-cooling plate such as that shown in FIG. 2B, and cools the second main surface 46 of the thermoelectric conversion member 12 of a water-cooling system. As shown in FIG. 2B, the cooler 14 includes a rectangular parallelepiped housing 14a and a pipe 14b disposed in the housing 14a. Two end portions of the pipe 14b project to the outside from a side surface of the housing 14a. A cooling fluid (for example, water) flows in from one end portion of the pipe 14b and flows through the pipe 14b in the housing 14a, and then is discharged to the outside from the other end portion of the pipe 14b. Therefore, the cooler 14 absorbs from the second main surface 46 heat obtained by radiant heat transferred to the first main surface 44 of the thermoelectric conversion member 12, and transfers the absorbed heat to the cooling fluid that flows through the pipe 14b. Note that, for convenience of illustration, FIG. 1 does not show the two end portions of the pipe 14b.

Note that, although, in the present embodiment, the reflecting member 8, the heat collector 10, and the cooler 14 are fixed to each other by the fixing member 6, the reflecting member 8 is preferably directly restricted by the cooler 14, and the heat collector 10 is preferably restricted by the cooler 14 through the heat-insulating member (supporting part 24). Therefore, stress that causes the thermoelectric conversion member 12 to be sandwiched between the heat collector 10 and the cooler 14 from two sides of the thermoelectric conversion member 12 can be applied to the thermoelectric conversion member 12, and heat transfer loss occurring when heat energy produced by radiant heat reaches the cooler 14 from the heat collector 10 through the thermoelectric conversion member 12 can be suppressed. As a result, it is possible to maximize the power generation amount of the thermoelectric conversion member 12 while keeping to a minimum heat transfer loss resulting from heat energy produced by the radiant heat reaching the cooler 14 through paths other than the thermoelectric conversion member 12.

The power generation amount of the thermoelectric conversion member 12 is also largely affected by the emissivity of the heat source 4. Therefore, the heat source 4 is preferably made of a material having high emissivity. For example, by performing alumite treatment on a surface of the heat source 4 and coating the surface with a black paint, it is possible to realize a more highly efficient thermoelectric conversion device 2. Note that, although, in the present embodiment, the heat source 4 is constituted by a solid exhaust heat source (structure), the heat source 4 is not limited thereto and thus the heat source 4 may be constituted by a fluid exhaust heat source, such as a vapor exhaust heat source.

### 1-2. Operation of Thermoelectric Conversion Device

While referring to FIG. 3, an operation of the thermoelectric conversion device 2 according to the first embodiment is described. FIG. 3 is a schematic view for illustrating the operation of the thermoelectric conversion device 2 according to the first embodiment.

As shown in FIG. 3, in the thermoelectric conversion device 2, the opening portion 32 of the reflecting member 8 is disposed so as to oppose the heat source 4. Radiant heat radiated from the heat source 4 passes through the opening portion 32 of the reflecting member 8. A part of the radiant heat that has passed through the opening portion 32 of the reflecting member 8 directly illuminates the heat-collecting region 40 of the heat collector 10 and is absorbed by the heat-collecting region 40. The other part of the radiant heat that has passed through the opening portion 32 of the reflecting member 8 is reflected by the reflecting surface 36 of the reflecting member 8, and then is collected at the heat-collecting point 38 in the heat-collecting region 40 and is absorbed by the heat-collecting region 40. The radiant heat absorbed by the heat-collecting region 40 is transferred to the heat transfer region 42 and then is further transferred to the first main surface 44 of the thermoelectric conversion member 12 from the heat transfer region 42.

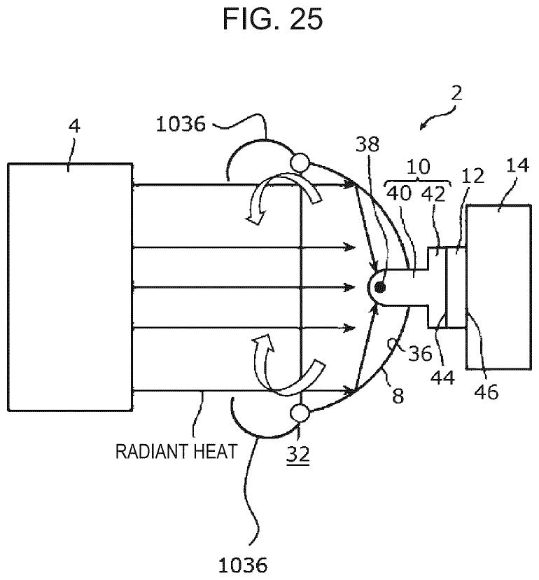

In the present embodiment, the opening portion 32 of the reflecting member 8 in the thermoelectric conversion device 2 may be disposed on an upper side of the heat source 4 (see FIG. 25). Therefore, heat that is based on the radiant heat radiated from the heat source 4 and that the thermoelectric conversion device 2 emits into the atmosphere is likely to remain in the vicinity of the heat-collecting region 40, and the heat-collecting region 40 can efficiently absorb the radiant heat.

An example of the heat described above that is based on the radiant heat radiated from the heat source 4 and that the thermoelectric conversion device 2 emits into the atmosphere is heat that is a part of the radiant heat radiated from the heat source 4 and absorbed by the reflecting surface 36 and that the reflecting surface 36 emits into the atmosphere.

The thermoelectric conversion device 2 may include a guide 1036. FIG. 25 is a diagram for illustrating the guide 1036. The guide 1036 is provided on an edge of the reflecting member 8. The guide 1036 has a structure that is wound inward. The guide 1036 makes it difficult for gas that is in a first space surrounded by the opening portion 32 and the reflecting surface 36 to move to a space other than the first space. The guide 1036 may be provided on an edge of the reflecting surface 36.

The guide 1036 makes it likely for heat that the reflecting surface 36 emits into the atmosphere to remain in the vicinity of the heat-collecting region 40. Therefore, it is possible to efficiently absorb the emitted heat.

The guide 1036 makes it likely for high-temperature gas that is produced by air current flowing toward the reflecting surface 36 from the heat source 8 to remain in the vicinity of the heat-collecting region 40. Therefore, the heat-collecting region 40 is likely to be maintained in a high-temperature state.

On the other hand, the cooler 14 absorbs from the second main surface 46 heat obtained by radiant heat transferred to the first main surface 44 of the thermoelectric conversion member 12, and transfers the absorbed heat to a cooling fluid, such as water or air.

Therefore, the thermoelectric conversion member 12 performs, by the Seebeck effect, thermoelectric power generation in which heat energy is converted into electric power by a temperature difference between the radiant heat absorbed by the heat-collecting region 40 of the heat collector 10 and the cooling fluid flowing in the cooler 14.

Effects of collecting radiant heat radiated from the heat source 4 by the heat collector 10 by using the reflecting member 8 are described below.

A heat flow rate Q in which infrared rays emitted from a surface of the heat source 4 at a temperature T₀ move into the heat collector 10 heated to a temperature T₁ is determined by the Stefan-Boltzmann law expressed in the following Formula (1):

$$Q = σ ( {T}_{o}^{4} {A}_{o} {α}_{0} - {T}_{1}^{4} {A}_{1} {α}_{1} ) \qquad ( 1 )$$

In the Formula (1) above, A₀ is the area of the opening portion 32 of the reflecting member 8, and A₁ is the surface area of the heat collector 10. α₀ is the proportion of the infrared rays emitted from the surface of the heat source 4, passing through the opening portion 32 of the reflecting member 8, and reaching the heat collector 10, and is a value that is greater than or equal to 0 and less than or equal to 1. Note that α₀ either is a) the emissivity of the heat source 4 or indicates that b) a radiant wave is a planar wave or a spherical wave; or α₀ depends upon c) the reflectivity of the reflecting surface 36 of the reflecting member 8 and d) the proportion of radiant heat that is reflected by the reflecting surface 36 and that reaches the heat collector 10. α₁ is the emissivity of the heat collector 10, and o is a Stefan-Boltzmann constant. By increasing the reflectivity of the reflecting member 8 and covering the heat-collecting point 38 by the heat collector 10, do can be increased, and, by decreasing the emissivity of the surface of the heat collector 10, a heat collection degree C. (=A₀α₀/A₁α₁) can be improved.

A heat-flow density Qₕ that passes through the first main surface 44 (high temperature side) of the thermoelectric conversion member 12 is expressed by the following Formula (2):

$${Q}_{h} = K ( {T}_{1} - {T}_{c} ) + N ( {S}_{p} - {S}_{n} ) {T}_{1} I - 1 / 2 {RI}_{2} \qquad ( 2 )$$

In the Formula (2) above, K is the heat conductivity of the thermoelectric conversion member 12, Sₚ and Sₙ are respectively the Seebeck coefficient of the P-type thermoelectric conversion element and the Seebeck coefficient of the N-type thermoelectric conversion element, N is the logarithm of the P-type thermoelectric conversion element and the logarithm of the N-type thermoelectric conversion element, R is the electric resistance of the thermoelectric conversion member 12, I is the electric current amount flowing through the thermoelectric conversion member 12, T₁ is a high-temperature-side temperature of the thermoelectric conversion member 12, and T_{c} is a low-temperature-side temperature of the thermoelectric conversion member 12.

In the thermoelectric conversion device 2 according to the first embodiment, Q=Qₕ is approximately established by a structure having a small heat dissipation loss. By increasing the heat collection degree C.=A₀α₀/A₁α₁ by a mirror structure provided by the reflecting member 8, while increasing T₁ up to a temperature close to T₀, it is possible to increase Q and Qₕ and, as a result, increase a temperature difference T₁−T_{c} to which the thermoelectric conversion member 12 is subjected.

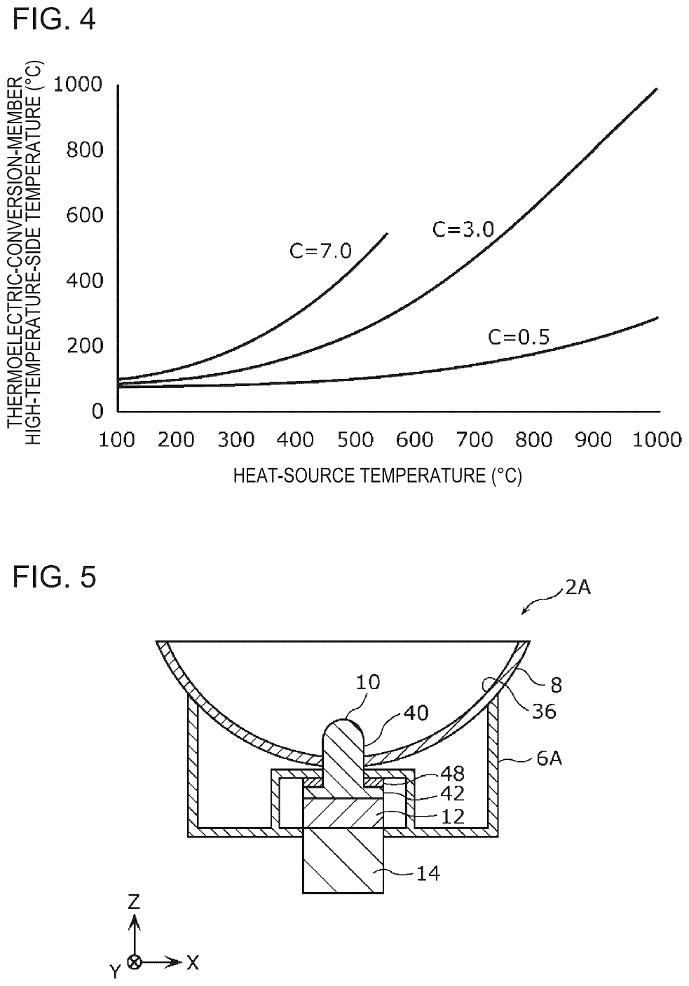

FIG. 4 is a graph showing dependence of the high-temperature-side temperature T₁ of the thermoelectric conversion member 12 on the temperature T₀ of the heat source 4, calculated as an example by using the Formulas (1) and (2). Here, as a parameter of the thermoelectric conversion member 12 per unit area, K=333 W/m²K is used, and since the contribution by the electric current I is relatively small, it is ignored. The temperature of the second main surface 46 of the thermoelectric conversion member 12 is 77° C.

As shown in FIG. 4, under a condition in which the reflecting member 8 and the heat collector 10 are not provided, due to, for example, heat dissipation loss, the heat collection degree becomes C=0.5, and even if the temperature T₀ of the heat source 4 is 1000° C., the high-temperature-side temperature of the thermoelectric conversion member 12 only increases to about 300° C. In contrast, as in the thermoelectric conversion device 2 according to the first embodiment, under a condition in which the reflecting member 8 and the heat collector 10 are provided, even if a heat source condition is of a lower quality such as the temperature T₀ of the heat source 4 being 500° C., it is possible to increase the heat collection degree up to C=about 3.0 or about 7, and to increase the high-temperature-side temperature of the thermoelectric conversion member 12 to a temperature close to the temperature T₀ of the heat source 4.

### 1-3. Effects

As described above, the thermoelectric conversion device 2 according to the first embodiment includes the reflecting member 8 and the heat collector 10. Therefore, the radiant heat radiated from the heat source 4 can be efficiently collected by the heat collector 10 after being reflected by the reflecting surface 36 of the reflecting member 8. As a result, heat obtained by the radiant heat can be converted into electric power with high efficiency.

Note that, although in the present embodiment, the supporting part 24 of the fixing member 6 is formed as a heat-insulating member, the supporting part is not limited thereto, and may be formed as shown in, for example, FIG. 5. FIG. 5 is a sectional view of a thermoelectric conversion device 2A according to a modification of the first embodiment.

As shown in FIG. 5, a heat-insulating member 48 is interposed between a fixing member 6A and the heat transfer region 42 of the heat collector 10. The heat-insulating member 48 is pushed toward the heat transfer region 42 of the heat collector 10 by the fixing member 6A. Even with such a structure, similarly to the first embodiment, stress that causes the thermoelectric conversion member 12 to be sandwiched by the heat collector 10 and the cooler 14 from two sides of the thermoelectric conversion member 12 can be applied to the thermoelectric conversion member 12, and heat transfer loss occurring when heat energy produced by radiant heat reaches the cooler 14 from the heat collector 10 through the thermoelectric conversion member 12 can be suppressed.

### 1-4. Modification of Heat Collector

### 1-4-1. Modification 1

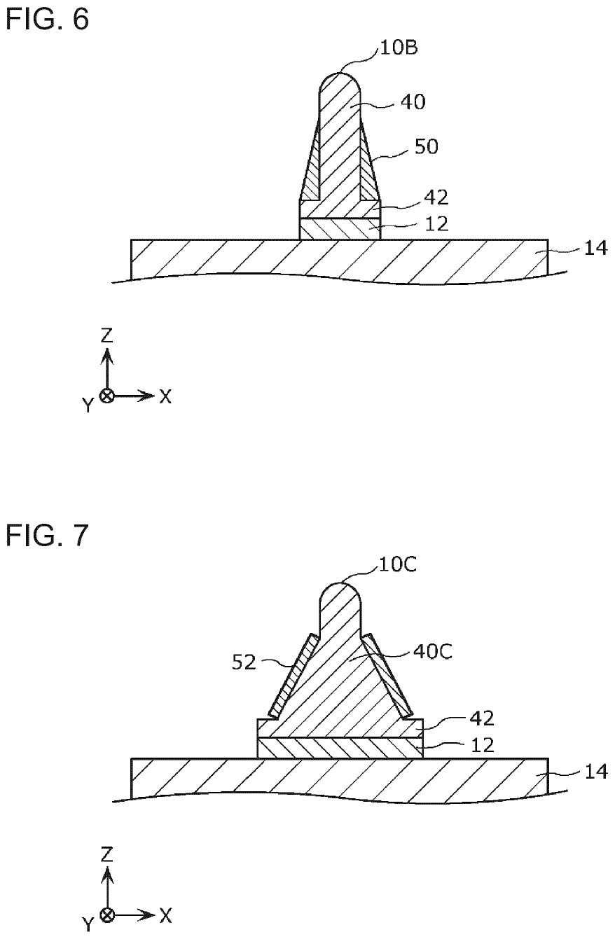

A structure of a heat collector 10B according to Modification 1 of the first embodiment is described with reference to FIG. 6. FIG. 6 is a sectional view of the heat collector 10B according to Modification 1 of the first embodiment.

As shown in FIG. 6, in the heat collector 10B according to Modification 1, a tapered heat-insulating member 50 is disposed along a side surface of the heat-collecting region 40. Radiant heat reflected by the reflecting surface 36 (see FIG. 2A) of the reflecting member 8 reaches the heat-collecting region 40 of the heat collector 10B along a tapering surface of the heat-insulating member 50. As a result, it is possible to increase the heat-collection efficiency of the reflecting member 8.

### 1-4-2. Modification 2

A structure of a heat collector 10C according to Modification 2 of the first embodiment is described with reference to FIG. 7. FIG. 7 is a sectional view of the heat collector 10C according to Modification 2 of the first embodiment.

As shown in FIG. 7, in the heat collector 10C according to Modification 2, a part of a side surface of a heat-collecting region 40C is formed to have a tapering shape. A heat-insulating member 52 is disposed along a tapering portion of the side surface of the heat-collecting region 40C. Therefore, radiant heat collected by the heat-collecting region 40C can be efficiently transferred to the thermoelectric conversion member 12.

### 1-4-3. Modification 3

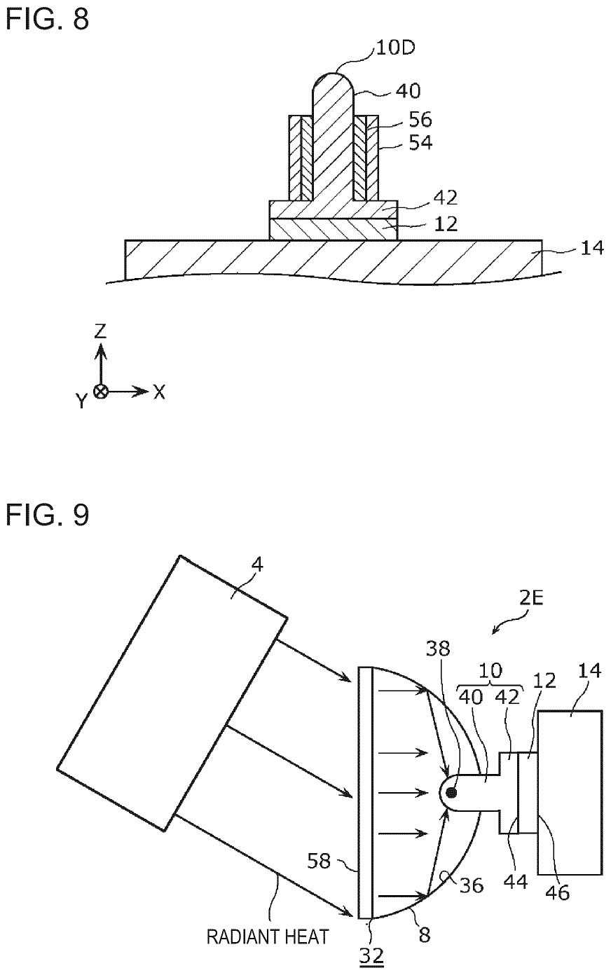

A structure of a heat collector 10D according to Modification 3 of the first embodiment is described with reference to FIG. 8. FIG. 8 is a sectional view of the heat collector 10D according to Modification 3 of the first embodiment.

As shown in FIG. 8, in the heat collector 10D according to Modification 3, a cylindrical heat-insulating member 54 is disposed along a side surface of the heat-collecting region 40 with a cylindrical heat storage member 56 being interposed therebetween. That is, the heat storage member 56 is disposed between the side surface of the heat-collecting region 40 (projecting structure) and the heat-insulating member 54, and stores heat absorbed by the heat-collecting region 40.

Therefore, even in a case in which the heat reception amount in the heat collector 10D varies, it is possible to smoothen out changes in the temperature difference in the thermoelectric conversion member 12 with time, and to more stably perform thermoelectric power generation. Note that the material of the heat storage member 56 is not particularly limited, and a proper material may be selected in accordance with the temperature of the radiant heat.

### Second Embodiment

A structure of a thermoelectric conversion device 2E according to a second embodiment is described with reference to FIG. 9. FIG. 9 is a schematic view showing the thermoelectric conversion device 2E according to the second embodiment. Note that, in each of the embodiments below, structural elements that correspond to those of the first embodiment are given the same reference numerals and are not described below.

As shown in FIG. 9, the thermoelectric conversion device 2E according to the second embodiment includes a heat collector 58 (an example of a second heat collector) in addition to the structural elements described in the first embodiment. The heat collector 58 is formed to have a circular plate shape, and is disposed at an opening portion 32 of a reflecting member 8 so as to oppose a reflecting surface 36 of the reflecting member 8. The heat collector 58 is made of, for example, aluminum, and a surface of the heat collector 58 is subjected to alumite treatment. Therefore, it is possible to relatively increase the emissivity of the surface of the heat collector 58. Note that, instead of the structure such as that described above, the heat collector 58 may be made of a metal material having a relatively high heat conductivity, such as copper or nickel, and the surface of the heat collector 58 may be coated with a black paint.

Note that, although not shown, the heat collector 58 is preferably connected to the opening portion 32 of the reflecting member 8 through a connection member made of a heat-insulating material. The connection member may be disposed along the entire periphery of the heat collector 58, or connection members may be disposed (that is, disposed in the form of a bridge) apart from each other along a peripheral direction of the heat collector 58.

Radiant heat from a heat source 4 is absorbed by a surface (surface on a side opposing the heat source 4) of the heat collector 58. The radiant heat absorbed by the surface of the heat collector 58 is further radiated toward the reflecting member 8 from a back surface (surface on a side opposing the reflecting member 8) of the heat collector 58, is reflected by the reflecting surface 36 of the reflecting member 8, and is then collected by a heat collector 10. At this time, since a radiation direction of the radiant heat from the back surface of the heat collector 58 is at all times a substantially perpendicular direction with respect to the back surface of the heat collector 58, even when the radiation direction of the radiant heat (infrared rays) from the heat source 4 with respect to the thermoelectric conversion device 2E varies, a heat-collecting point 38 can be kept constant.

Note that since heat transfer caused by convection of air in the reflecting member 8 causes reverse flow of heat, this may lead to heat collection loss. In such a case, with a connection member made of a heat-insulating material being interposed between an outer peripheral portion of the heat collector 58 and a peripheral edge portion of the opening portion 32 of the reflecting member 8, by bringing the inside of the reflecting member 8 into a vacuum state, it is possible to suppress the heat transfer by the convection of air. In addition, due to such a structure, it is possible to suppress a reduction in the reflectivity caused by soiling of the reflecting surface 36 of the reflecting member 8.

### Third Embodiment

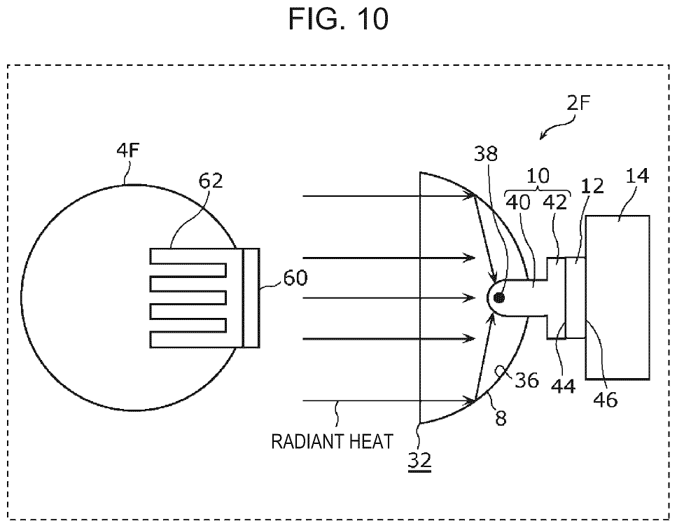

A structure of a thermoelectric conversion device 2F according to a third embodiment is described with reference to FIG. 10. FIG. 10 is a schematic view showing the thermoelectric conversion device 2F according to the third embodiment.

As shown in FIG. 10, the thermoelectric conversion device 2F according to the third embodiment includes a heat collector 60 (an example of a third heat collector) and a fin 62, in addition to the structural elements described in the first embodiment.

The heat collector 60 is disposed between a heat source 4F and an opening portion 32 of a reflecting member 8. Specifically, the heat collector 60 is disposed along a side surface of the heat source 4F. The heat collector 60 is made of, for example, aluminum, and a surface of the heat collector 60 is subjected to alumite treatment. Therefore, it is possible to relatively increase the emissivity of the surface of the heat collector 60. Note that, instead of the structure such as that described above, the heat collector 60 may be made of a metal material having a relatively high heat conductivity, such as copper or nickel, and the surface of the heat collector 60 may be coated with a black paint.

The fin 62 is disposed so as to project toward the inside of the heat source 4F from a back surface of the heat collector 60. Note that the heat source 4F is a pipe in which, for example, a high-temperature fluid, such as a high-temperature gas, flows.

Heat of the high-temperature fluid that flows in the heat source 4F is transferred to the heat collector 60 through the fin 62. The heat transferred to the heat collector 60 is radiated as radiant heat toward the reflecting member 8 of the thermoelectric conversion device 2F from the heat collector 60. Therefore, the heat of the high-temperature fluid that flows in the heat source 4F can be efficiently transferred to a heat collector 10.

In the thermoelectric conversion device 2F of a non-contact system such as that in the present embodiment, it is possible to reduce effects of, for example, changes in radiation temperature with time, or vibration, or pulsation, resulting from the high-temperature fluid flowing in the heat source 4F, on a thermoelectric conversion member 12; and to perform thermoelectric power generation in the thermoelectric conversion member 12 while protecting the thermoelectric conversion member 12 that is weak against shock or stress.

### Fourth Embodiment

### 4-1. Functional Structure of Thermoelectric Conversion System

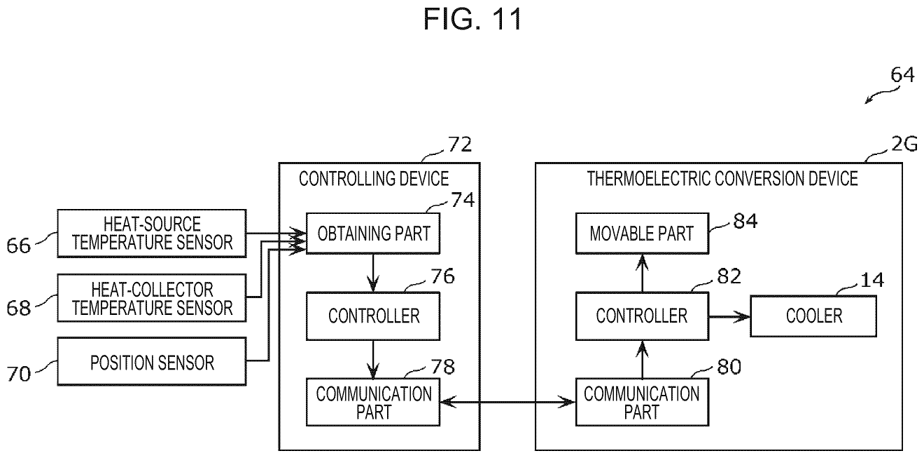

A functional structure of a thermoelectric conversion system 64 according to a fourth embodiment is described with reference to FIG. 11. FIG. 11 is a block diagram showing the functional structure of the thermoelectric conversion system 64 according to the fourth embodiment.

As shown in FIG. 11, the thermoelectric conversion system 64 according to the fourth embodiment includes a heat-source temperature sensor 66, a heat-collector temperature sensor 68, a position sensor 70, a controlling device 72, and a thermoelectric conversion device 2G.

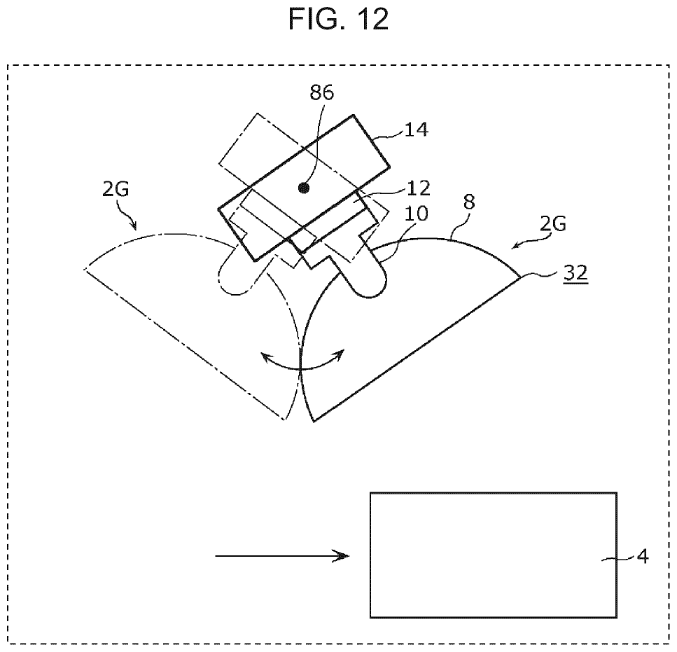

The heat-source temperature sensor 66 is a temperature sensor for detecting the ambient temperature the heat source 4 (see FIG. 12 described below). The heat-source temperature sensor 66 outputs to the controlling device 72 heat-source temperature information indicating the detected temperature of the heat source 4.

The heat-collector temperature sensor 68 is a temperature sensor for detecting the ambient temperature of the heat collector 10 (see FIG. 12 described below), and is, for example, a thermocouple. The heat-collector temperature sensor 68 outputs to the controlling device 72 heat-collector temperature information indicating the detected temperature of the heat collector 10.

The position sensor 70 detects the positional relationship between the heat source 4 and thermoelectric conversion device 2G. The position sensor 70 outputs to the controlling device 72 position information indicating the detected positional relationship.

The controlling device 72 is a device for controlling the thermoelectric conversion device 2G. The controlling device 72 includes an obtaining part 74, a controller 76, and a communication part 78.

The obtaining part 74 obtains the heat-source temperature information from the heat-source temperature sensor 66, the heat-collector temperature information from the heat-collector temperature sensor 68, and the position information from the position sensor 70. The obtaining part 74 outputs to the controller 76 the obtained heat-source temperature information, the obtained heat-collector temperature information, and the obtained position information.

On the basis of the heat-source temperature information and the position information from the obtaining part 74, the controller 76 generates a first control signal including changing information for instructing the thermoelectric conversion device 2G to change at least one of the position and the angle of the thermoelectric conversion device 2G with respect to the heat source 4. In addition, on the basis of the heat-collector temperature information from the obtaining part 74, the controller 76 generates a second control signal for controlling the cooling capability of a cooler 14 of the thermoelectric conversion device 2G.

The communication part 78 sends to the thermoelectric conversion device 2G the first control signal and the second control signal generated by the controller 76.

The thermoelectric conversion device 2G includes a communication part 80, a controller 82, a movable part 84, and the cooler 14.

The communication part 80 receives the first control signal and the second control signal that have been sent from the controlling device 72.

On the basis of the first control signal received by the communication part 80, the controller 82 controls the movable part 84 to change at least one of the position and the angle of the thermoelectric conversion device 2G with respect to the heat source 4. On the basis of the second control signal received by the communication part 80, the controller 82 controls the cooler 14 to change the cooling capability of the cooler 14.

The movable part 84 is provided for moving or rotating the thermoelectric conversion device 2G with respect to the heat source 4.

As described in the first embodiment, the cooler 14 is provided for cooling the second main surface 46 (see FIG. 2A) of the thermoelectric conversion member 12. Note that, by adjusting the flow rate of a cooling fluid that flows in the cooler 14 or the rotation speed or the like of a blower fan of the cooler 14, it is possible to change the cooling capability of the cooler 14.

### 4-2. Control Example 1 of Controlling Device

While referring to FIG. 12, Control Example 1 of the controlling device 72 according to the fourth embodiment is described. FIG. 12 is a schematic view for illustrating Control Example 1 of the controlling device 72 according to the fourth embodiment.

As shown in FIG. 12, in Control Example 1, the first control signal includes as follows changing information for instructing the thermoelectric conversion device 2G. The changing information is information for giving an instruction to change the angle of the thermoelectric conversion device 2G with respect to the heat source 4 such that the temperature of the heat collector 10 in the thermoelectric conversion device 2G becomes higher than a first temperature. Therefore, the movable part 84 (see FIG. 11) of the thermoelectric conversion device 2G rotates the thermoelectric conversion device 2G around a rotation axis 86 with respect to the heat source 4 such that an opening portion 32 of a reflecting member 8 follows the movement of the heat source 4 that is transported on, for example, a conveyor (not shown).

Therefore, in Control Example 1, radiant heat that is radiated from the heat source 4 can be efficiently collected by the heat collector 10. Note that, in Control Example 1, the first control signal may include as follows changing information for instructing the thermoelectric conversion device 2G. The changing information is information for giving an instruction to change the position of the thermoelectric conversion device 2G with respect to the heat source 4 such that the temperature of the heat collector 10 in the thermoelectric conversion device 2G becomes higher than the first temperature.

### 4-3. Control Example 2 of Controlling Device

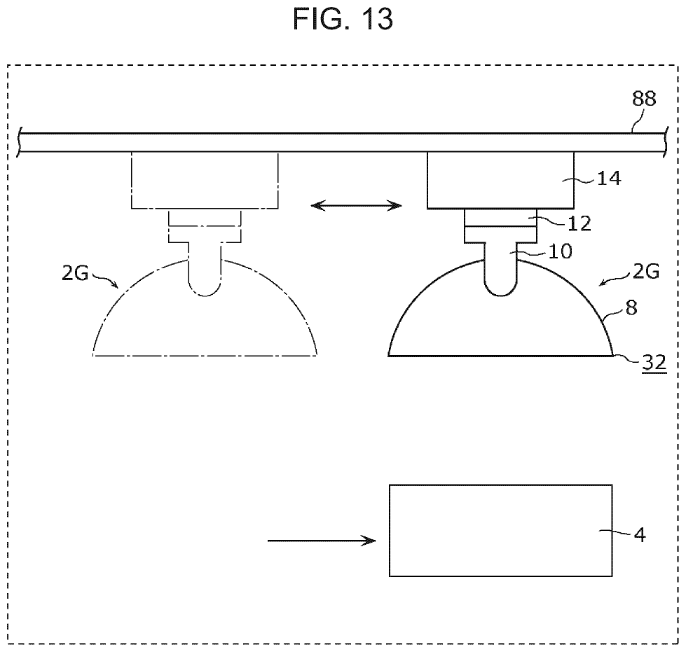

While referring to FIG. 13, Control Example 2 of the controlling device 72 according to the fourth embodiment is described. FIG. 13 is a schematic view for illustrating Control Example 2 of the controlling device 72 according to the fourth embodiment.

As shown in FIG. 13, in Control Example 2, the first control signal includes as follows changing information for instructing the thermoelectric conversion device 2G. The changing information is information for giving an instruction to change the position of the thermoelectric conversion device with respect to the heat source 4 so as to follow changes in the ambient temperature of the heat source 4 indicated by the heat-source temperature information. Therefore, the controller 82 (see FIG. 11) of the thermoelectric conversion device 2G predicts an ambient temperature distribution of the heat source 4 after t seconds from a present time on the basis of the first control signal, and controls the movable part 84 on the basis of the predicted result. The movable part 84 (see FIG. 11) of the thermoelectric conversion device 2G moves the thermoelectric conversion device 2G along a rail 88 with respect to the heat source 4 such that the opening portion 32 of the reflecting member 8 follows the movement of the heat source 4 that is transported on, for example, a conveyor (not shown).

Therefore, in Control Example 2, similarly to Control Example 1 above, radiant heat radiated from the heat source 4 can be efficiently collected by the heat collector 10. Note that, in Control Example 2, the first control signal may include as follows changing information for instructing the thermoelectric conversion device 2G. The changing information is information for giving an instruction to change the angle of the thermoelectric conversion device with respect to the heat source 4 so as to follow changes in the ambient temperature of the heat source 4 indicated by the heat-source temperature information.

### 4-4. Control Example 3 of Controlling Device

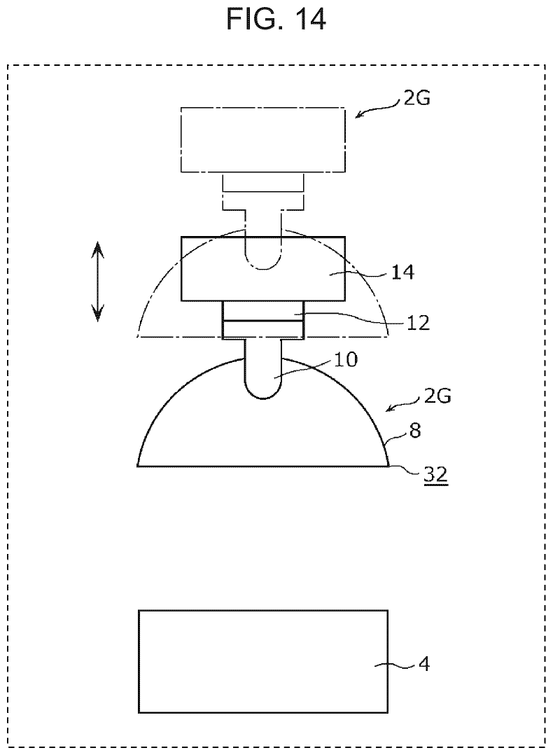

While referring to FIG. 14, Control Example 3 of the controlling device 72 according to the fourth embodiment is described. FIG. 14 is a schematic view for illustrating Control Example 3 of the controlling device 72 according to the fourth embodiment.

As shown in FIG. 14, in Control Example 3, the first control signal includes as follows changing information for instructing the thermoelectric conversion device 2G. The changing information is information for giving an instruction to change the position of the thermoelectric conversion device 2G with respect to the heat source 4 such that the thermoelectric conversion device 2G moves away from the heat source 4 when the ambient temperature of the heat source 4 indicated by the heat-source temperature information exceeds a second temperature. Therefore, the movable part 84 (see FIG. 11) of the thermoelectric conversion device 2G moves the thermoelectric conversion device 2G along a rail (not shown) with respect to the heat source 4 such that the thermoelectric conversion device 2G moves away from the heat source 4.

Therefore, in Control Example 3, the distance between the heat source 4 and the thermoelectric conversion device 2G can be properly maintained in accordance with the ambient temperature of the heat source 4. By properly maintaining the distance between the heat source 4 and the thermoelectric conversion device 2G, it is possible to prevent deterioration of the thermoelectric conversion device 2G caused by an excessive temperature rise exceeding the heat resistance limit of the thermoelectric conversion device 2G. Note that, in Control Example 3, the first control signal may include as follows changing information for instructing the thermoelectric conversion device 2G. The changing information is information for giving an instruction to change the angle of the thermoelectric conversion device 2G with respect the heat source 4 such that the thermoelectric conversion device 2G moves away from the heat source 4 when the ambient temperature of the heat source 4 indicated by the heat-source temperature information exceeds the second temperature.

### 4-5. Control Example 5 of Controlling Device

In Control Example 5, the controller 82 of the thermoelectric conversion device 2G controls the cooler 14 so as to change the cooling capability of the cooler 14 on the basis of the second control signal. Specifically, when the ambient temperature of the heat collector 10 is relatively high, the controller 82 controls the cooler 14 so as to increase the cooling capability of the cooler 14, and, when the ambient temperature of the heat collector 10 is relatively low, the controller 82 controls the cooler 14 so as to decrease the cooling capability of the cooler 14. Therefore, it is possible to increase the efficiency of the thermoelectric power generation in the thermoelectric conversion member 12.

### Fifth Embodiment

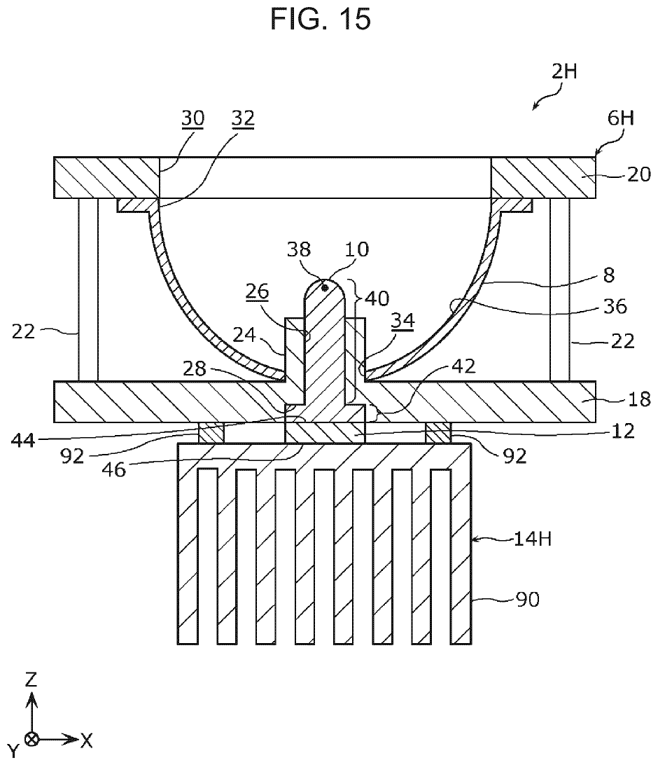

A structure of a thermoelectric conversion device 2H according to a fifth embodiment is described with reference to FIG. 15. FIG. 15 is a sectional view of the thermoelectric conversion device 2H according to the fifth embodiment.

As shown in FIG. 15, the thermoelectric conversion device 2H according to the fifth embodiment differs from the first embodiment in the structures of a fixing member 6H and a cooler 14H.

The fixing member 6H includes a second plate 18, a third plate 20, and connecting rods 22, and does not include the first plate 16 described in the first embodiment. Therefore, the fixing member 6H fixes a reflecting member 8 and a heat collector 10 to each other.

The cooler 14H cools a second main surface 46 of a thermoelectric conversion member 12 of an air-cooling system. Specifically, the cooler 14H includes a heat sink 90 made of, for example, a metal having high heat dissipation, such as aluminum. The heat sink 90 is fixed to a lower surface of the second plate 18 of the fixing member 6H through a heat-sink fixing part 92. The heat sink 90 contacts the second main surface 46 of the thermoelectric conversion member 12. Heat from the second main surface 46 of the thermoelectric conversion member 12 is transferred to the heat sink 90, and is dissipated into the atmosphere from the heat sink 90.

### Sixth Embodiment

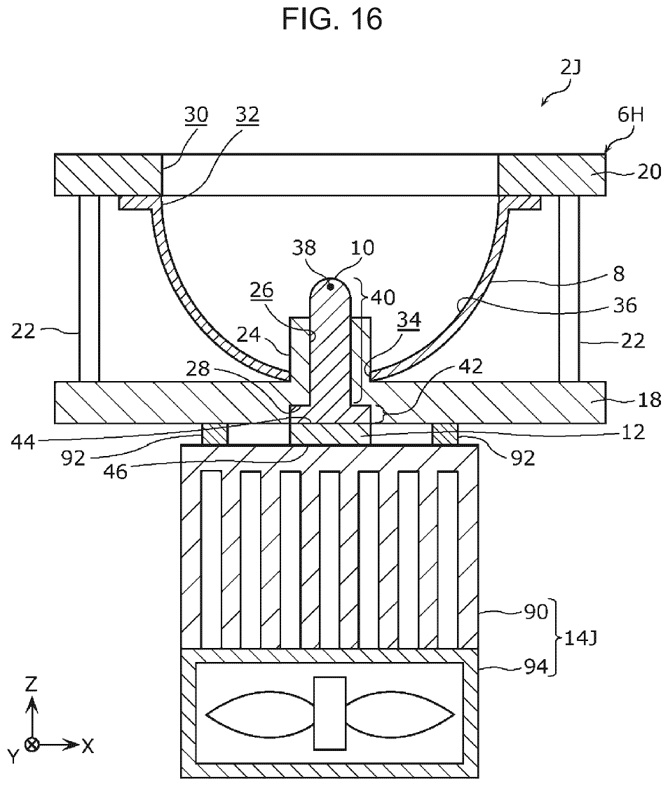

A structure of a thermoelectric conversion device 2J according to a sixth embodiment is described with reference to FIG. 16. FIG. 16 is a sectional view of the thermoelectric conversion device 2J according to the sixth embodiment.

As shown in FIG. 16, the thermoelectric conversion device 2J according to the sixth embodiment differs from the fifth embodiment in the structure of a cooler 14J. Specifically, the cooler 14J includes a blower fan 94 in addition to the heat sink 90 described in the fifth embodiment. The blower fan 94 is disposed, for example, below the heat sink 90. Heat from a second main surface 46 of a thermoelectric conversion member 12 is transferred to the heat sink 90, and the heat of the heat sink 90 is air-cooled by cooling air from the blower fan 94.

### Seventh Embodiment

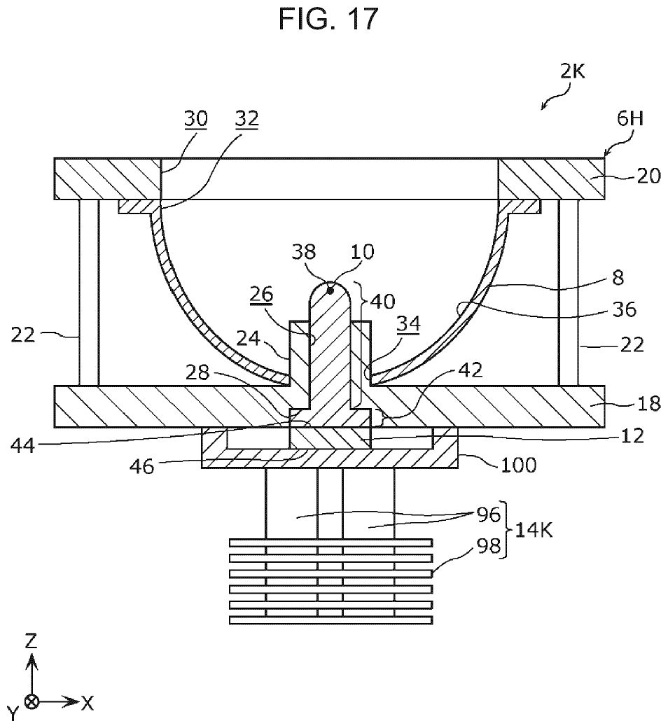

A structure of a thermoelectric conversion device 2K according to a seventh embodiment is described with reference to FIG. 17. FIG. 17 is a sectional view of the thermoelectric conversion device 2K according to the seventh embodiment.

As shown in FIG. 17, the thermoelectric conversion device 2K according to the seventh embodiment differs from the first embodiment in the structure of a cooler 14K. Specifically, the cooler 14K includes a heat pipe 96 and a heat sink 98. The heat pipe 96 is fixed to a lower surface of a second plate 18 of a fixing member 6H through a heat-pipe fixing part 100. The heat pipe 96 contacts a second main surface 46 of a thermoelectric conversion member 12 through the heat-pipe fixing part 100. The heat sink 98 is made of, for example, a metal having high heat dissipation, such as aluminum, and is disposed so as to contact a surface of the heat pipe 96.

In the cooler 14K described above, by using a water evaporation/condensation effect in the heat pipe 96, heat from the second main surface 46 of the thermoelectric conversion member 12 is transferred to the heat pipe 96. The heat transferred to the heat pipe 96 is further transferred to the heat sink 98 and is dissipated into the atmosphere from the heat sink 98.

### Eighth Embodiment

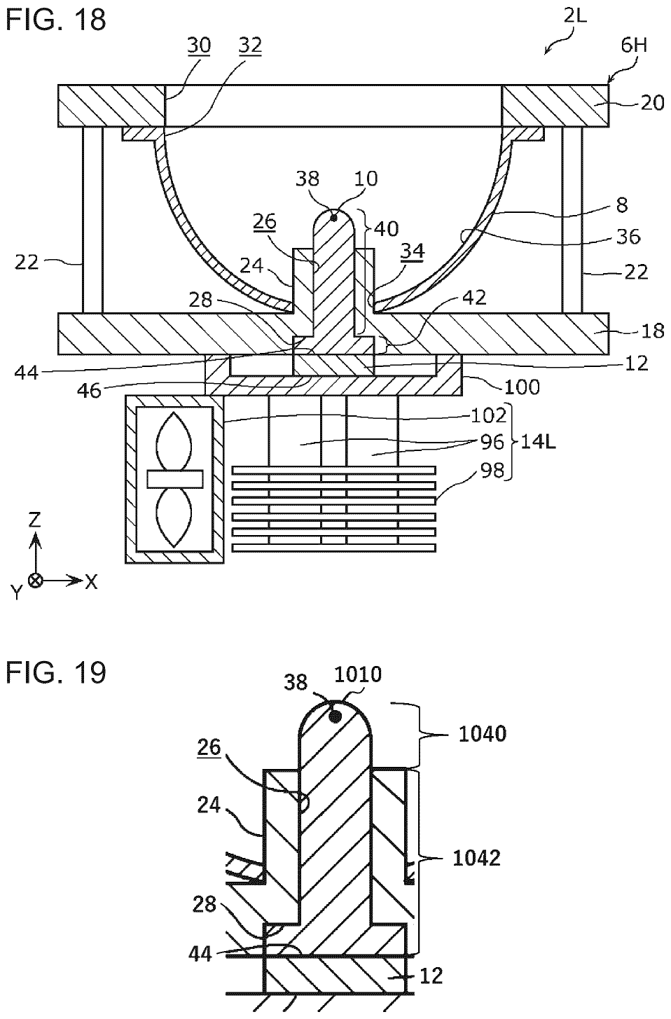

A structure of a thermoelectric conversion device 2L according to an eighth embodiment is described with reference to FIG. 18. FIG. 18 is a sectional view of the thermoelectric conversion device 2L according to the eighth embodiment.

As shown in FIG. 18, the thermoelectric conversion device 2L according to the eighth embodiment differs from the seventh embodiment in the structure of a cooler 14L. Specifically, the cooler 14L includes a blower fan 102 in addition to the heat pipe 96 and the heat sink 98 described in the seventh embodiment. The blower fan 102 is disposed, for example, laterally with respect to the heat pipe 96.

In the cooler 14L described above, by using a water evaporation/condensation effect in the heat pipe 96, heat from a second main surface 46 of a thermoelectric conversion member 12 is transferred to the heat pipe 96. The heat transferred to the heat pipe 96 is further transferred to the heat sink 98, and the heat of the heat sink 98 is air-cooled by cooling air from the blower fan 102.

### Other Embodiments

Although, with regard to a thermoelectric conversion device according to one aspect of the present disclosure or thermoelectric conversion devices according to aspects of the present disclosure, a description has been given on the basis of each embodiment and each modification, the present disclosure is not limited to each of these embodiments and each of these modifications. Each of these embodiments and each of these modifications variously modified by any person skilled in the art may be included within the scope of the one aspect or the aspects of the present disclosure as long as the various modifications do not depart from the spirit of the present disclosure.

### Others

Modifications of the embodiments of the present disclosure may be as follows.

A thermoelectric conversion device according to a first section includes
a reflecting member (for example, 8) that has a reflecting surface (for example, 36) that reflects first radiant heat;
a first heat collector (for example, 1010/FIG. 19) that includes a first region (for example, 1040/FIG. 19) and a second region (for example, 1042/FIG. 19); and
a thermoelectric conversion member (for example, 12) that converts heat into electric power,
wherein the reflecting surface is a concave surface,
wherein the first region (for example, 1040) receives the reflected first radiant heat,
wherein the second region (for example, 1042) transfers heat based on the reflected first radiant heat to the thermoelectric conversion member,
wherein the first region (for example, 1040) faces the reflecting surface (for example, 36), and
wherein a third region that is included in the second region (for example, 1042A) is provided between the reflecting member (for example, 8) and the thermoelectric conversion member (for example, 12).

A thermoelectric conversion device according to a second section based on the thermoelectric conversion device according to the first section further includes
a heat-insulating member (for example, 48/FIG. 21),
wherein the heat-insulating member (for example, 48/FIG. 21) directly or indirectly contacts the second region (for example, 1042A).

In a thermoelectric conversion device according to a third section based on the thermoelectric conversion device according to the second section,
the third region is provided between the heat-insulating member (for example, 48/FIG. 21) and the thermoelectric conversion member (for example, 12).

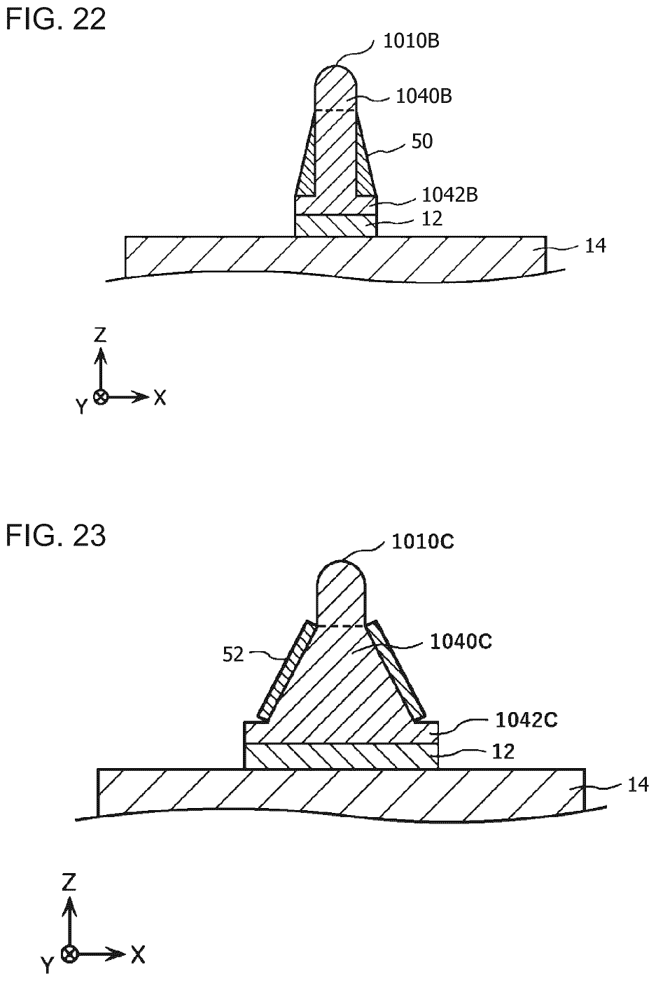

In a thermoelectric conversion device according to a fourth section based on the thermoelectric conversion device according to the second section or the third section,
the first region (for example, 1040A/FIG. 21) projects from the reflecting surface, and
the heat-insulating member (for example, 48/FIG. 21, 50/FIG. 22, 52/FIG. 23) is provided along a side surface of the second region (for example, 1042A/FIG. 21, 1042B/FIG. 22, 1042C/FIG. 23).

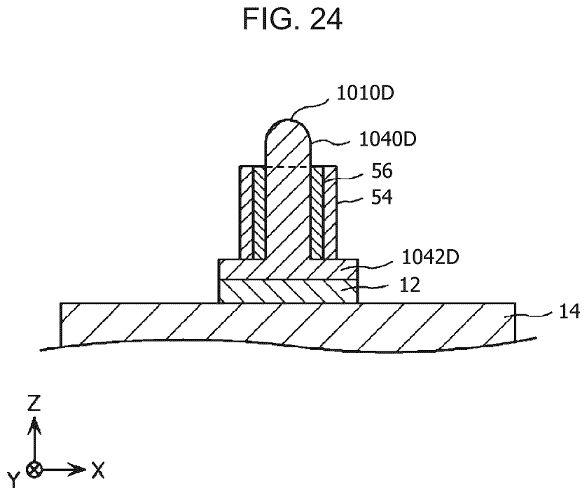

A thermoelectric conversion device according to a fifth section based on the thermoelectric conversion device according to the fourth section, further includes
a heat storage member (for example, 56/FIG. 24) that stores heat,
wherein the heat storage member is provided between the second region (for example, 1042D/FIG. 24) and the heat-insulating member (for example, 54/FIG. 24).

In a thermoelectric conversion device according to a sixth section based on the thermoelectric conversion device according to any one of the first section to the fifth section,
an emissivity of a surface of the first region is greater than or equal to 0.8, and a heat conductivity at an inner portion of the first region is greater than or equal to 20 W/mK.

In a thermoelectric conversion device according to a seventh section based on the thermoelectric conversion device according to the sixth section, the surface of the first region is coated with a black paint, or is subjected to alumite treatment.

In a thermoelectric conversion device according to an eighth section based on the thermoelectric conversion device according to any one of the first section to the seventh section,
a cross section of the reflecting surface has an elliptical arc shape, an arc shape, or a parabolic shape.

A thermoelectric conversion device according to a ninth section based on the thermoelectric conversion device according to any one of the first section to the eighth section, further includes
a cooler (for example, 14) that cools the thermoelectric conversion member,
wherein the thermoelectric conversion member has a first main surface that contacts the second region and a second main surface that contacts the cooler.

In a thermoelectric conversion device according to a tenth section based on the thermoelectric conversion device according to any one of the first section to the ninth section,
the reflecting member (for example, 8) has an opening (for example, 32),
the first radiant heat is second radiant heat that has passed through the opening, and
the second radiant heat is based on radiant heat that the heat source has output.

In a thermoelectric conversion device according to an eleventh section based on the thermoelectric conversion device according to any one of the first section to the ninth section,
the reflecting member (for example, 8) includes a second heat collector (for example, 58),
the second heat collector opposes the reflecting surface,
the first radiant heat is third radiant heat that the second heat collector has output,
the third radiant heat is based on fourth radiant heat that the second heat collector has received, and
the fourth radiant heat is based on radiant heat that the heat source has output.

A thermoelectric conversion device according to a twelfth section based on the thermoelectric conversion device according to any one of the first section to the ninth section, further includes
a third heat collector (60) that is disposed between the heat source and the reflecting member,
wherein the third heat collector receives heat from the heat source,
wherein the reflecting member (for example, 8) has an opening (for example, 32),
wherein the first radiant heat is second radiant heat that has passed through the opening,
wherein the second radiant heat is based on radiant heat that the third heat collector has output, and
wherein the radiant heat is based on the heat that the third heat collector has received.

A thermoelectric conversion device according to a thirteenth section based on the thermoelectric conversion device according to any one of the first section to the ninth section, further includes
a third heat collector (for example, 60) that is disposed between the heat source and the reflecting member,
wherein the third heat collector receives heat from the heat source,
wherein the reflecting member (for example, 8) includes a second heat collector (for example, 58),
wherein the second heat collector opposes the reflecting surface,
wherein the first radiant heat is third radiant heat that the second heat collector has output,
wherein the third radiant heat is based on fourth radiant heat that the second heat collector has received,
wherein the fourth radiant heat is based on radiant heat that the third heat collector has output, and
wherein the radiant heat is based on the heat that the third heat collector has received.

FIG. 19 is a diagram for illustrating a first region and a second region. A heat collector 1010 includes a first region 1040 and a second region 1042. FIG. 19 is a diagram corresponding to a part of the thermoelectric conversion device 2 shown in FIG. 2A. FIG. 19 shows a part of the thermoelectric conversion device 2 in which the heat collector 10 in the thermoelectric conversion device 2 shown in FIG. 2A has been replaced by the heat collector 1010. Portions of the thermoelectric conversion device 2 whose illustrations have been omitted in FIG. 19 are the same as the portions included in the thermoelectric conversion device 2 shown in FIG. 2A and corresponding to the omitted portions. The differences between FIG. 19 and FIG. 2A are that the heat collector 1010 in FIG. 19 includes the first region 1040 and the second region 1042, and that the heat collector 10 in FIG. 2A includes the heat-collecting region 40 and the heat transfer region 42.

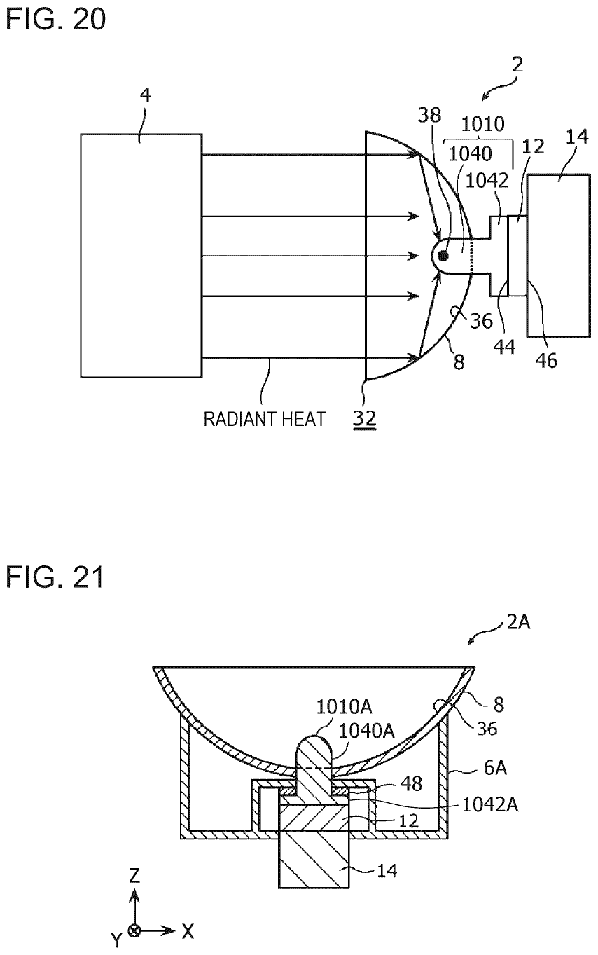

FIG. 20 is a diagram for illustrating a first region and a second region. The heat collector 1010 includes the first region 1040 and the second region 1042. FIG. 20 corresponds to FIG. 3. The differences between FIG. 20 and FIG. 3 are that the heat collector 1010 in FIG. 20 includes the first region 1040 and the second region 1042, and that the heat collector 10 in FIG. 3 includes the heat-collecting region 40 and the heat transfer region 42.

FIG. 21 is a diagram for illustrating a first region and a second region. A heat collector 1010A includes a first region 1040A and a second region 1042A. FIG. 21 corresponds to FIG. 5. The differences between FIG. 21 and FIG. 5 are that the heat collector 1010A in FIG. 21 includes the first region 1040A and the second region 1042A, and that the heat collector 10 in FIG. 5 includes the heat-collecting region 40 and the heat transfer region 42.

FIG. 22 is a diagram for illustrating a first region and a second region. A heat collector 1010B includes a first region 1040B and a second region 1042B. FIG. 22 corresponds to FIG. 6. The differences between FIG. 22 and FIG. 6 are that the heat collector 1010B in FIG. 22 includes the first region 1040B and the second region 1042B, and that the heat collector 10B in FIG. 6 includes the heat-collecting region 40 and the heat transfer region 42.

FIG. 23 is a diagram for illustrating a first region and a second region. A heat collector 1010C includes a first region 1040C and a second region 1042C. FIG. 23 corresponds to FIG. 7. The differences between FIG. 23 and FIG. 7 are that the heat collector 1010C in FIG. 23 includes the first region 1040C and the second region 1042C, and that the heat collector 10C in FIG. 7 includes the heat-collecting region 40C and the heat transfer region 42.

FIG. 24 is a diagram for illustrating a first region and a second region. A heat collector 1010D includes a first region 1040D and a second region 1042D. FIG. 24 corresponds to FIG. 8. The differences between FIG. 24 and FIG. 8 are that the heat collector 1010D in FIG. 24 includes the first region 1040D and the second region 1042D, and that the heat collector 10D in FIG. 8 includes the heat-collecting region 40 and the heat transfer region 42.

The present disclosure is applicable as, for example, a thermoelectric conversion device that generates electric power by using radiant heat that is radiated from a heat source.

What is claimed is:

1. A thermoelectric conversion device comprising:
a reflecting member that has an opening portion through which radiant heat from a heat source passes, and a concave reflecting surface that reflects the radiant heat that has passed through the opening portion;
a thermoelectric conversion member that converts heat into electric power; and
a first heat collector that is disposed between the reflecting member and the thermoelectric conversion member, and that is disposed such that at least a part of the first heat collector faces the reflecting surface of the reflecting member,
wherein the first heat collector includes a heat-collecting region that absorbs the radiant heat reflected by the reflecting surface of the reflecting member, and a heat transfer region that transfers the radiant heat absorbed by the heat-collecting region to the thermoelectric conversion member.

2. The thermoelectric conversion device according to claim 1, further comprising:
a heat-insulating member that is disposed at least a part of the heat transfer region.

3. The thermoelectric conversion device according to claim 2,
wherein at least a part of the first heat collector is sandwiched between the heat-insulating member and the thermoelectric conversion member.

4. The thermoelectric conversion device according to claim 2,
wherein the heat-collecting region has a projecting structure that projects toward the opening portion from the reflecting surface of the reflecting member,
wherein the projecting structure has an end portion and a side surface, and
wherein the heat-insulating member is disposed along the side surface of the projecting structure.

5. The thermoelectric conversion device according to claim 4, further comprising:
a heat storage member that stores heat absorbed by the heat-collecting region,
wherein the heat storage member is disposed between the side surface of the projecting structure and the heat-insulating member.

6. The thermoelectric conversion device according to claim 1,
wherein an emissivity of a surface of the heat-collecting region is greater than or equal to 0.8, and a heat conductivity of an inner portion of the heat-collecting region is greater than or equal to 20 W/mK.

7. The thermoelectric conversion device according to claim 6,
wherein the surface of the heat-collecting region is subjected to alumite treatment, or is coated with a black paint.

8. The thermoelectric conversion device according to claim 1,
wherein a cross-sectional shape of the reflecting surface of the reflecting member includes at least one of an elliptical arc shape, an arc shape, or a parabolic shape.

9. The thermoelectric conversion device according to claim 1, further comprising:
a cooler that cools the thermoelectric conversion member; and
a fixing member that fixes the reflecting member and the first heat collector to each other,
wherein the thermoelectric conversion member has a first main surface that contacts the heat transfer region of the first heat collector, and a second main surface that contacts the cooler.

10. The thermoelectric conversion device according to claim 1, further comprising:
a second heat collector that is disposed at the opening portion so as to oppose the reflecting surface of the reflecting member, and that absorbs the radiant heat from the heat source.

11. The thermoelectric conversion device according to claim 1, further comprising:
a third heat collector that is disposed between the heat source and the opening portion of the reflecting member,
wherein the third heat collector absorbs heat from the heat source, and radiates, as the radiant heat, the heat that has been absorbed toward the reflecting member.

12. A controlling method that is performed by a controlling device for controlling the thermoelectric conversion device according to claim 1,
wherein the controlling device
(a) obtains position information indicating a positional relationship between the heat source and the thermoelectric conversion device;
(b) based on at least the position information obtained in the (a), generates a first control signal including changing information for instructing the thermoelectric conversion device to change at least one of a position or an angle of the thermoelectric conversion device with respect to the heat source; and
(c) sends the first control signal generated in the (b) to the thermoelectric conversion device.

13. The controlling method according to claim 12,
wherein, in the (b), the first control signal including the changing information is generated based on heat-source temperature information and the position information, the heat-source temperature information indicating an ambient temperature of the heat source, and
wherein the first control signal includes the changing information for instructing the thermoelectric conversion device to perform at least one of
(1) changing at least one of the position or the angle of the thermoelectric conversion device with respect to the heat source such that a temperature of the first heat collector in the thermoelectric conversion device becomes higher than a first temperature;
(2) changing at least one of the position or the angle of the thermoelectric conversion device with respect to the heat source so as to follow a change in the ambient temperature of the heat source indicated by the heat-source temperature information; or
(3) changing at least one of the position or the angle of the thermoelectric conversion device with respect to the heat source such that the thermoelectric conversion device moves away from the heat source when the ambient temperature of the heat source indicated by the heat-source temperature information exceeds a second temperature.

14. A controlling method that is performed by a controlling device for controlling the thermoelectric conversion device according to claim 9,
wherein the controlling device
(a) obtains heat-collector temperature information indicating an ambient temperature of the first heat collector;
(b) based on the heat-collector temperature information obtained in the (a), generates a second control signal for controlling a cooling capability of the cooler of the thermoelectric conversion device; and
(c) sends the second control signal generated in the (b) to the thermoelectric conversion device.

15. A method of generating electric power, comprising:
reflecting radiant heat from a heat source having a peak wavelength that is greater than or equal to 3 μm;
absorbing heat obtained by the radiant heat that has been reflected;
transferring the heat that has been absorbed; and
converting the heat that has been transferred into the electric power.
